(19) United States
(12) Patent Application Publication
(10) Pub. No.: US 2013/0056067 A1
(43) Pub. Date: Mar. 7, 2013

(54) Photovoltaic Module and Method of Manufacturing the Same

(71) Applicants: Chih-He YEN, Hong Kong (HK); Hsuan-Ping Chen, Kaohsiung City (TW)

(72) Inventors: Chih-He YEN, Hong Kong (HK); Hsuan-Ping Chen, Kaohsiung City (TW)

(73) Assignee: Du Pont Apollo Limited, Hong Kong (HK)

(21) Appl. No.: 13/224,339

(22) Filed: Sep. 2, 2011

(51) Int. Cl. H01L 31/0203

(52) U.S. Cl. 136/259; 438/64; 257/E31.117

(57) ABSTRACT

A photovoltaic module includes at least one photovoltaic cell, a back plate, at least two ribbons, an encapsulant layer, and a filler. The back plate is disposed over the photovoltaic cell, in which the back plate has a ribbon hole therein. The ribbons are electrically connected to the photovoltaic cell and pass through the ribbon hole. The encapsulant layer is disposed between the back plate and the photovoltaic cell, in which the encapsulant layer has at least one through hole therein, and both of the ribbons pass through the through hole. The filler fills the through hole of the encapsulant layer, in which a flowability of a material of the filler is greater than a flowability of a material of the encapsulant layer.

### BACKGROUND

1. Technical Field

The present disclosure relates to a photovoltaic module and a method of manufacturing the same.

2. Description of Related Art

Photovoltaic (PV) modules are units capable of converting radiant energy, the energy of the sun, into an electrical energy with the aid of photovoltaic cells. A conventional photovoltaic module (PV module) is typically in a laminated structure, which includes at least a photovoltaic cell, a front transparent substrate, and a back plate. In general, the individual photovoltaic cell may be inter-connected by electrical wirings, such as ribbons. The photovoltaic cell may be further laminated to an encapsulant layer. The encapsulant layer protects the photovoltaic cell from weather or moisture as well as provides the mechanical strength for the photovoltaic module. The electrical wirings of the photovoltaic module may also be laminated to the encapsulant layer and each has one end linked to a junction box. The junction box is typically mounted on a back or a rear side of the photovoltaic module for the electrical connection of the individual photovoltaic module.

In a general junction box back mounting design, the electrical wirings may be designed to lead out from a ribbon hole in the back plate and the encapsulant layer. However, the ribbon hole in the back plate of the photovoltaic module may cause the encapsulant layer to be exposed to sun light or oxygen directly. The conventional encapsulant layer material, such as ethylene vinyl acetate (EVA), may have some issues as it exposed to sun light. For examples, EVA is easily being decomposed under sun light and then further degraded in presence of oxygen and heat. In addition, peroxide, normally applied for EVA crosslinking, may also cause EVA turning into yellow color under a heat and humid condition. On the other hand, the moisture or vapor may easily migrate into the photovoltaic module via the ribbon hole in the back plate. Therefore, the conventional photovoltaic modules may have shelf-life issue as it exposed to sun light and humid environments. The applications of conventional back mounting design of the photovoltaic modules are limited.

In order to make the photovoltaic modules to be widely and common used devices, it is necessary to build the photovoltaic modules with better reliability. For this purpose, it is also necessary to improve the conventional back mounting structures of the photovoltaic modules and the method of manufacturing the same, thereby meeting the above requirements.

### SUMMARY

According to one embodiment of the present invention, a photovoltaic module includes at least one photovoltaic cell, a back plate, at least two ribbons, an encapsulant layer, and a filler. The back plate is disposed over the photovoltaic cell, in which the back plate has a ribbon hole therein. The ribbons are electrically connected to the photovoltaic cell and pass through the ribbon hole. The encapsulant layer is disposed between the back plate and the photovoltaic cell, in which the encapsulant layer has at least one through hole therein, and both of the ribbons pass through the through hole. The filler fills the through hole of the encapsulant layer, in which a flowability of a material of the filler is greater than a flowability of a material of the encapsulant layer.

According to another embodiment of the present invention, a method of manufacturing a photovoltaic module includes the following steps. At least one through hole is formed in an encapsulant layer. At least two ribbons are electrically connected to a photovoltaic cell. The encapsulant layer is positioned on the photovoltaic cell in such a manner that the ribbons pass through the through hole. The through hole is filled with a filler, and the ribbons protrude from the filler, in which a flowability of a material of the filler is greater than a flowability of a material of the encapsulant layer.

### BRIEF DESCRIPTION OF THE DRAWINGS

FIG. 1 is an exploded view of a photovoltaic module according to one embodiment of the present disclosure; and

FIG. 2 is a cross-sectional view of a photovoltaic module according to one embodiment of the present disclosure.

### DETAILED DESCRIPTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

References in the singular may also include the plural (for example, “a” and “an” may refer to one, or one or more) unless the context specifically states otherwise. The use of numerical values in the various ranges specified in this application, unless expressly indicated otherwise, are stated as approximations as though the minimum and maximum values within the stated ranges were both preceded by the word “about”. In this manner, slight variations above and below the stated ranges can be used to achieve substantially the same results as values within the ranges. Also, the disclosure of these ranges is intended as a continuous range including every value between the minimum and maximum values.

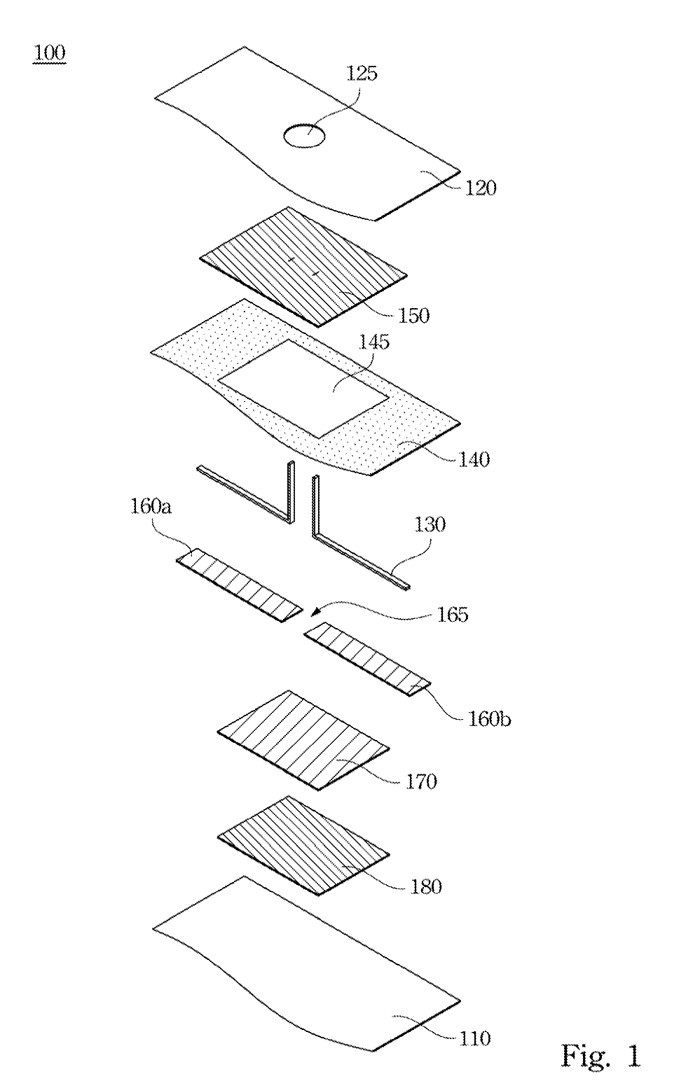

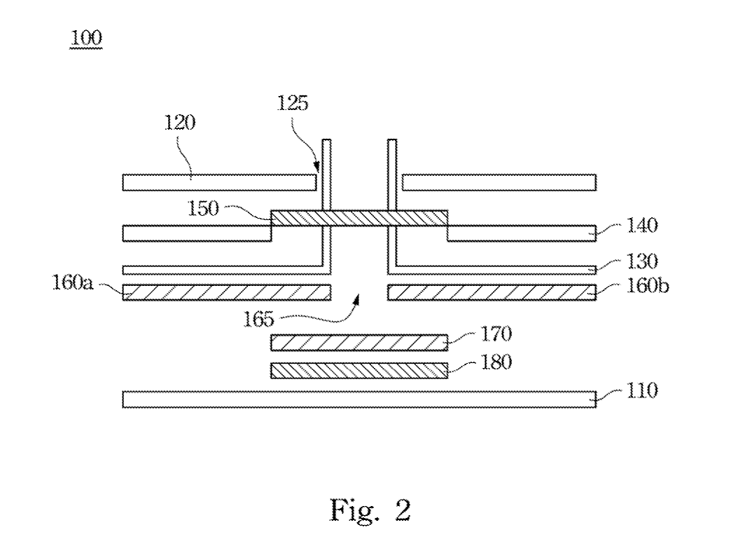

FIG. 1 is an exploded view of a photovoltaic module 100 according to one embodiment of the present disclosure. FIG. 2 is a cross-sectional of a photovoltaic module 100 view according to one embodiment of the present disclosure. A photovoltaic module 100 includes at least one photovoltaic cell 110, a back plate 120, at least two ribbons 130, an encapsulant layer 140, and a filler 150. The back plate 120 is disposed over the photovoltaic cell 110, in which the back plate 120 has a ribbon hole 125 therein. The ribbons 130 are electrically connected to the photovoltaic cell 110 and pass through the ribbon hole 125. The encapsulant layer 140 is disposed between the back plate 120 and the photovoltaic cell 110, in which the encapsulant layer 140 has at least one through hole 145 therein, and both of the ribbons 130 pass through the through hole 145. The filler 150 fills the through hole 145 of the encapsulant layer 140, in which a flowability of a material of the filler 150 is greater than a flowability of a material of the encapsulant layer 140.

In some cases, a full piece of ionomer is typically applied as the encapsulant layer to solve the issues which caused by using an EVA encapsulant layer. Since the ionomer is a material with a low flowability, bubbles and voids may exist between the encapsulant layer and the photovoltaic cell after the lamination process. Therefore, a cooling system for conducting a vacuum lamination process may be necessary to reduce the bubbles or voids formation. However, such a cooling system is costly and expensively, the long process time may reduce a yield of the photovoltaic modules production as well.

Accordingly, in one or more embodiments of present disclosure, the through hole 145 is provided in the encapsulant layer 140, and the through hole 145 is filled with the filler 150. Since the flowability of the material of the filler 150 is greater than the flowability of the material of the encapsulant layer 140, the filler 150 can fill voids between the filler 150 and the photovoltaic cell 110 during the lamination process. As a result, a possibility of formation of bubbles and voids between the encapsulant layer 140/the filler 150 and the photovoltaic cell 110 are substantially eliminated, and therefore the reliability is remarkably enhanced. On the other hand, the laminated photovoltaic module 100 may be free of edge bubbles without employing the cooling system, the manufacturing cost can be reduced, as well as the production yield can also be improved.

In one or more embodiments of present disclosure, the photovoltaic cell 110 (also called solar cell) is a solid state device that converts irradiate of light into an electric energy by photovoltaic effect. The photovoltaic cell 110 used herein may be in a wafer type or in a thin-film type, in which the wafer type photovoltaic cell 110 may be made of monocrystalline silicon (c-Si) or poly-crystalline silicon (poly-Si or mc-Si), and the thin-film photovoltaic cell 110 may be made of amorphous silicon (a-Si), microcrystalline silicon (uc-Si), cadmium telluride (CdTe), copper indium gallium selenide (CIGS) or copper indium selenide (CIS).

In one or more embodiments of present disclosure, the ribbons 130 may each has one end leaded out of the photovoltaic module 100 to be electrically connected to a junction box.

In other of present disclosure, the amount of the ribbon holes 125 may be two, and the ribbons may pass through the ribbon holes 125 respectively. The back plate 120 may be a multi-layered laminate sheet, such as a backsheet, or a glass.

The encapsulant layer 140 applied herein is to provide a moisture resistance and a mechanical strength for the photovoltaic module 100. In one embodiment, the encapsulant layer 140 may be made of an ionomer. In one or more embodiments, the ionomer may be copolymers formed by partially or fully neutralizing the carboxylic acid groups of precursor or parent polymers that are acid copolymers comprising copolymerized residues of a α-olefins and α- or β-ethylenically unsaturated carboxylic acids.

When the encapsulant layer 140 is made of an ionomer, the flowability of the material of the filler 150 is greater than the ionomer. The filler 150 may be made of ethylene-vinyl acetate copolymer (EVA), silicone, polyvinylbutyral (PVB), thermoplastic polyurethane (TPU) or combinations thereof. In one embodiment, the filler 150 may have at least one slit or hole therein so that the ribbons 130 may pass through the slit or hole. In particular, the filler 150 may have two slits or holes.

In addition, the photovoltaic module 100 further includes an insulating sheet 170 disposed between the encapsulant layer 140 and the photovoltaic cell 110. In one embodiment, a main surface area of the filler 150 is greater than or equal to a main surface area of the insulating sheet 170. The insulating sheet 170 is made of polyethylene terephthalate (PET).

The term “main surface” as used herein means “one of the sides of an object whose area is largest among the sides of an object”. In particular, the filler 150 and/or the insulating sheet 170 each has two opposite main surfaces and four side surfaces, and the area of each main surface of the filler 150 and/or the insulating sheet 170 is greater the area of each side surface of the filler 150 and/or the insulating sheet 170.

Moreover, the photovoltaic module 100 further includes a first insulating layer 160a and a second insulating layer 160b disposed between the insulating sheet 170 the ribbons 130, thereby forming an opening 165 between the first is insulating layer 160a and the second insulating layer 160b, in which the opening 165 of the insulating layer 160 is aligned with the through hole 145 of the encapsulant layer 140. In particular, each of the first 160a and second insulating layer 160b has a portion overlay on a portion of the insulating sheet. In particular, the first 160a and second insulating layer 160b are below the ribbons 130. In addition, in one and more embodiments, the first insulating layer 160a has a first main surface, the second insulating layer 160b has a second main surface, and the first and the second main surface are greater than a main surface of the ribbons.

The insulating sheet 170 and the first/second insulating layer 160a/160b are collectively used to ensure insulation between the ribbons 130 and the photovoltaic cell 110. In one embodiment, the first/second insulating layer 160a/160b and the insulating sheet 170 are made of the same material. The first/second insulating layer 160a/160b may be made of a material that could provide the insulation and vapor-barrier properties. For example, the first/second insulating layer 160a/160b may be made of polyethylene terephthalate (PET).

Furthermore, the photovoltaic module 100 further includes an adhesive layer 180 disposed between the insulating sheet 170 and the photovoltaic cell 110. The insulating sheet 170 is bounded to the photovoltaic cell 110 via the to adhesive layer 170. The adhesive layer 180 may have a size the same as a size of the insulating sheet 170. In general, the size of each of the adhesive layer 180 and the insulating sheet 170 is greater than or equal to a size of the ribbon holes 125 of the back plate 120 in order to prevent water or vapor to migrate into the photovoltaic cell 110. In one embodiment, the filler 150 and the adhesive layer 180 are made of the same material. For example, the adhesive layer 180 may be made of ethylene-vinyl acetate copolymer (EVA), silicone, polyvinylbutyral (PVB), thermoplastic polyurethane (TPU), or combinations thereof.

In another aspect, the present disclosure provides a method of manufacturing the photovoltaic module 100. The method of manufacturing the photovoltaic module 100 includes the following steps. At least one through hole 145 is formed in an encapsulant layer 140. At least two ribbons are electrically connected to a photovoltaic cell 110. The encapsulant layer 140 is positioned on the photovoltaic cell 110 in such a manner that the ribbons 130 pass through the through hole 145. The through hole 145 is filled with a filler 150, and the ribbons 130 protrude from the filler 150.

In one embodiment, a flowability of a material of the filler 150 is greater than a flowability of a material of the encapsulant layer 140. In other embodiment, the encapsulant layer is made of an ionomer.

In addition, an adhesive layer 180 may be positioned on the photovoltaic cell 110 before the ribbons 130 are electrically connected to the photovoltaic cell 110. In one embodiment, the filler 150 and the adhesive layer 180 are made of the same material. The filler 150 may be made of ethylene-vinyl acetate copolymer (EVA), silicone, polyvinylbutyral (PVB), thermoplastic polyurethane (TPU), or combinations thereof. Similarly, the adhesive layer 180 may be made of ethylene-vinyl acetate copolymer (EVA), silicone, polyvinylbutyral (PVB), thermoplastic polyurethane (TPU), or combinations thereof as well.

Moreover, an insulating sheet 170 may be positioned on the adhesive layer 180. In one embodiment, a main surface area of the filler 150 is greater than or equal to a main surface area of the insulating sheet 170. The insulating sheet 170 is made of polyethylene terephthalate (PET).

According to another embodiment of present disclosure, a first insulating layer 160a and a second insulating layer 160b may be positioned on the insulating sheet 170 thereby an opening is formed between the first insulating layer and the second insulating layer, in which the opening is aligned with the insulating sheet. In particular, the first insulating layer 160a and the second insulating layer 160b are below the ribbons 130.

In one or more embodiments, the first insulating layer 160a has a first main surface, the second insulating layer 160b has a second main surface, and the first and the second main surface are greater than a main surface of the ribbons 130.

Then, the whole structure is laminated to form the photovoltaic module 100. In this step, a vacuum lamination process may be employed. The vacuum lamination process may be performed at a temperature of 130-160° C. or 80-170° C., under pressure of 30-100 Kpa or 20-100 Kpa. The vacuum time may be set at least 5 minutes or 2-10 minutes, and the holding time may be set at least 5 minutes or 2-10 minutes. The vacuum lamination process can be performed without any cooling system, and the laminated photovoltaic module 100 is found to be free of edge bubbles.

It will be apparent to those skilled in the art that various modifications and variations can be made to the structure of the present invention without is departing from the scope or spirit of the invention. In view of the foregoing, it is intended that the present invention cover modifications and variations of this invention provided they fall within the scope of the following claims.

What is claimed is:

1. A photovoltaic module comprising:
at least one photovoltaic cell;
a back plate disposed over the photovoltaic cell, wherein the back plate has a ribbon hole therein;
at least two ribbons electrically connected to the photovoltaic cell and passing through the ribbon hole;
an encapsulant layer disposed between the back plate and the photovoltaic cell, wherein the encapsulant layer has at least one through hole therein, and both of the ribbons pass through the through hole; and
a filler filling the through hole of the encapsulant layer, wherein a flowability of a material of the filler is greater than a flowability of a material of the encapsulant layer.

2. The photovoltaic module of claim 1, further comprising an insulating sheet disposed between the encapsulant layer and the photovoltaic cell.

3. The photovoltaic module of claim 2, wherein a main surface area of the filler is greater than or equal to a main surface area of the insulating sheet.

4. The photovoltaic module of claim 2, further comprising a first insulating layer and a second insulating layer disposed between the insulating sheet and the ribbons thereby forming an opening between the first insulating layer and second insulating layer, wherein the opening is aligned with the through hole of the encapsulant layer.

5. The photovoltaic module of claim 4, wherein the first insulating layer has a first main surface, the second insulating layer has a second main surface, and the first and the second main surface are greater than a main surface of the ribbons.

6. The photovoltaic module of claim 4, wherein the insulating layer and the insulating sheet are made of the same material.

7. The photovoltaic module of claim 6, wherein the insulating layer is made of polyethylene terephthalate (PET).

8. The photovoltaic module of claim 2, wherein the filler is positioned directly above the insulating sheet.

9. The photovoltaic module of claim 2, further comprising an adhesive layer disposed between the insulating sheet and the photovoltaic cell.

10. The photovoltaic module of claim 9, wherein the adhesive layer is made of a material selected from the group consisting of ethylene-vinyl acetate copolymer (EVA), silicone, polyvinylbutyral (PVB), thermoplastic polyurethane (TPU), and combinations there of.

11. The photovoltaic module of claim 1, wherein the filler is made of a material selected from the group consisting of ethylene-vinyl acetate copolymer (EVA), silicone, polyvinylbutyral (PVB) and thermoplastic polyurethane (TPU), and combinations there of.

12. The photovoltaic module of claim 1, wherein the encapsulant layer is made of an ionomer.

13. A method of manufacturing a photovoltaic module, the method comprising:
forming at least one through hole in an encapsulant layer;
electrically connecting at least two ribbons to a photovoltaic cell;
positioning the encapsulant layer on the photovoltaic cell in such a manner that the ribbons pass through the through hole; and
filling the through hole with a filler and making the ribbons protrude from the filler, wherein a flowability of a material of the filler is greater than a flowability of a material of the encapsulant layer.

14. The method of claim 13, further comprising:
positioning an adhesive layer on the photovoltaic cell before electrically connecting the ribbons to the photovoltaic cell.

15. The method of claim 14, further comprising:
positioning an insulating sheet on the adhesive layer.

16. The method of claim 15, wherein a main surface area of the filler is greater than or equal to a main surface area of the insulating sheet.

17. The method of claim 15, further comprising:
positioning a first insulating layer and a second insulating layer on the insulating sheet thereby forming an opening between the first insulating layer and the second insulating layer, wherein the opening is aligned with the insulating sheet.

18. The method of claim 17, wherein the first insulating layer has a first main surface, the second insulating layer has a second main surface, and the first and the second main surface are greater than a main surface of the ribbons.

19. The method of claim 13, wherein the filler is made of a material selected from the group consisting of ethylene-vinyl acetate copolymer (EVA), is silicone, polyvinylbutyral (PVB), thermoplastic polyurethane (TPU), and combinations thereof.

20. The method of claim 13, wherein the encapsulant layer is made of an ionomer.
